(19) United States
(12) Patent Application Publication
(10) Pub. No.: US 2010/0210042 A1
(43) Pub. Date: Aug. 19, 2010

(54) METHOD OF MANUFACTURING SEMICONDUCTOR MODULE

(75) Inventors: Hyun-Jong OH, Seoul (KR); Seong-Chan HAN, Cheonan-si (KR); Jae-Hoon CHOI, Cheonan-si (KR); Chan-Hyung YUN, Asan-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD., Suwon-si (KR)

(21) Appl. No.: 12/705,729

(22) Filed: Feb. 15, 2010

(30) Foreign Application Priority Data
Feb. 16, 2009 (KR) 10-2009-0012508

(51) Int. Cl. H01L 21/66; H01L 21/50

(52) U.S. Cl. 438/15; 438/16; 438/106; 257/E21.499; 257/E21.521

(57) ABSTRACT

A method of manufacturing a semiconductor module is provided. A semiconductor package is formed, having one or more plate units which are bent by heat. The semiconductor package is aligned on a module substrate, and connection members are disposed between the semiconductor package and the module substrate. Heat is applied to the plate units and the connection members to extend a distance between the module substrate and the semiconductor package, and connection patterns are formed. The height of the connection patterns is larger than that of the connection members.

### PRIORITY STATEMENT

This application claims priority from Korean Patent Application No. 10-2009-0012508, filed on Feb. 16, 2009, the contents of which are hereby incorporated herein by reference in its entirety.

### SUMMARY

Methods consistent with the exemplary embodiments relate to a method of manufacturing a semiconductor module, and more specifically, to a method of manufacturing a semiconductor module, which can adjust the heights of connection patterns formed between a semiconductor package and a module substrate using plate units on which different kinds of metal layers having different thermal expansion coefficients are stacked.

The development of semiconductor packages is showing a tendency toward lighter, thinner, shorter, and smaller designs and higher capacity. To reduce the size and weight of semiconductor packages, the size of semiconductor chips composing a semiconductor package and the line width of circuit interconnections are being reduced. Further, in order to provide high-capacity semiconductor packages, the development of a stacked package having a plurality of semiconductor chips or unit packages stacked therein is being accelerated. Accordingly, the circuit line width of semiconductor chips and the size of connection patterns such as solder balls are decreasing, and the number of connection patterns is increasing.

Meanwhile, as the size of the semiconductor chip decreases, a semiconductor package having a fan-out structure is being developed, in which connection patterns are formed at positions on the lower surface of a substrate, the positions deviating from the edges of the semiconductor chip. In the semiconductor package having a fan-out structure, however, cracks may occur on the connection patterns formed at the positions deviating from the edges of the semiconductor chip, which means that TC reliability of solder joint portions is low.

As the number of connection patterns of a semiconductor package increases, a method of electrically connecting a semiconductor package and a module substrate using solder without solder balls is being developed. However, since the connection patterns formed by using the solder have a small aspect ratio, TC reliability of solder joint portions decreases.

The above-described connection patterns such as solder balls have a small aspect ratio because they are formed by the natural surface tension and the weight of the semiconductor package. Therefore, artificial methods capable of adjusting the height of connection patterns have been developed, but are difficult to apply to a belt-type reflow process which is being used in most industrial fields.

Therefore, there is a demand for a new method which, when connecting a semiconductor package and a module substrate, can increase the aspect ratio of connection patterns to improve the TC reliability of electrical connection portions.

One or more exemplary embodiments provide a method of manufacturing a semiconductor module which can form high-reliability connection patterns between a semiconductor package and a module substrate.

One or more exemplary embodiments provide a method of manufacturing a semiconductor module. A semiconductor package may be formed, having one or more plate units which are bent by heat. The semiconductor package may be aligned on a module substrate, and connection members may be disposed between the semiconductor package and the module substrate. Heat may be applied to the plate units and the connection members to extend a distance between the module substrate and the semiconductor package, and connection patterns may be formed. The height of the connection patterns may be larger than that of the connection members.

According to one or more exemplary embodiments, forming the semiconductor package may include forming a substrate having a body, the plate units, and fixing parts connecting the body to the plate units. The plate units may include stacked metal layers having different thermal expansion coefficients. A semiconductor chip may be formed on the substrate to be electrically connected to the substrate. A mold unit covering the semiconductor chip may be formed on the substrate.

In one more exemplary embodiments, the plate units may be formed outside the opposite edges of the body.

In one more exemplary embodiments, the plate units may be formed outside all the edges of the body to be spaced from the body.

In one more exemplary embodiments, the fixing parts may be formed between central portions of the plate units and the body.

In one more exemplary embodiments, the thermal expansion coefficients of the metal layers of the plate units may gradually decrease toward the connection patterns.

In one more exemplary embodiments, the fixing parts may be formed between both end portions of the plate units and the body.

In one more exemplary embodiments, the thermal expansion coefficients of the metal layers of the plate units may gradually increase toward the connection patterns.

In one more exemplary embodiments, forming the semiconductor package may include forming a package body having a substrate, a semiconductor chip, and a mold unit. The semiconductor chip may be attached on the substrate, and the mold unit may be formed on the substrate to cover the semiconductor chip. The plate units may be attached to edges of the package body using fixing parts. The plate units may have stacked metal layers having different thermal expansion coefficients.

In one more exemplary embodiments, the metal layers may be formed of a bi-metal or shape memory alloy.

### BRIEF DESCRIPTION OF THE DRAWINGS

Exemplary embodiments are described in further detail below with reference to the accompanying drawings. It should be understood that various aspects of the drawings may have been exaggerated for clarity.

FIG. 1 is a schematic perspective view of a semiconductor package according to a first exemplary embodiment.

FIG. 2 is a cross-sectional view taken along line I-I′ of FIG. 1.

FIG. 3 is a plan view showing a lower surface of the semiconductor package of FIG. 1.

FIG. 4 is a cross-sectional view taken along line II-IF of FIG. 3.

FIG. 5 is a cross-sectional view taken along line III-III′ of FIG. 3.

FIGS. 6A to 6C are cross-sectional views illustrating a method of manufacturing a semiconductor module using the semiconductor package according to the first exemplary embodiment.

FIG. 7 is a schematic perspective view of a semiconductor package according to a second exemplary embodiment.

FIG. 8 is a plan view showing a lower surface of the semiconductor package according to the second exemplary embodiment.

FIG. 9 is a cross-sectional view illustrating a method of manufacturing a semiconductor module using the semiconductor package according to the second exemplary embodiment.

FIG. 10 is a plan view showing a lower surface of a semiconductor package according to a third exemplary embodiment.

FIG. 11 is a perspective view of a semiconductor package according to a fourth exemplary embodiment.

FIG. 12 is a cross-sectional view taken along line IV-IV′ of FIG. 11.

FIGS. 13A to 13C are cross-sectional views illustrating a method of manufacturing a semiconductor module using the semiconductor package according to the fourth exemplary embodiment.

FIG. 14 is a perspective view of a semiconductor package according to a fifth exemplary embodiment.

FIGS. 15A and 15B are perspective views of the semiconductor package having a clip part mounted thereon according to exemplary embodiments.

FIG. 16 is a perspective view of a semiconductor package according to a sixth exemplary embodiment.

FIG. 17 is a perspective view of a semiconductor package according to a seventh exemplary embodiment.

FIG. 18 is a cross-sectional view taken along line V-V′ of FIG. 17.

### DETAILED DESCRIPTION OF EXEMPLARY EMBODIMENTS

Various exemplary embodiments will now be described more fully with reference to the accompanying drawings in which some exemplary embodiments are shown. In the drawings, the thicknesses of layers and regions may be exaggerated for clarity.

Detailed illustrative embodiments are disclosed herein. However, specific structural and functional details disclosed herein are merely representative for purposes of describing exemplary embodiments. This inventive concept, however, may be embodied in many alternate forms and should not be construed as limited to only the exemplary embodiments set forth herein.

Accordingly, while exemplary embodiments are capable of various modifications and alternative forms, only some exemplary embodiments are shown by way of example in the drawings and will herein be described in detail. It should be understood, however, that there is no intent to limit exemplary embodiments to the particular forms disclosed, but on the contrary, the exemplary embodiments are to cover all modifications, equivalents, and alternatives thereof. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of exemplary embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of the exemplary embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof. Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, may be expected. Thus, exemplary embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and are not limiting.

It should also be noted that in some alternative implementations, the functions noted may occur out of the order noted in the figures. For example, two figures shown in succession may in fact be executed substantially concurrently or may sometimes be executed in the reverse order, depending upon the functionality involved.

In order to more specifically describe exemplary embodiments, various aspects will be described in detail with reference to the attached drawings. However, the scope of the attached claims is not limited to exemplary embodiments described.

### First Exemplary Embodiment

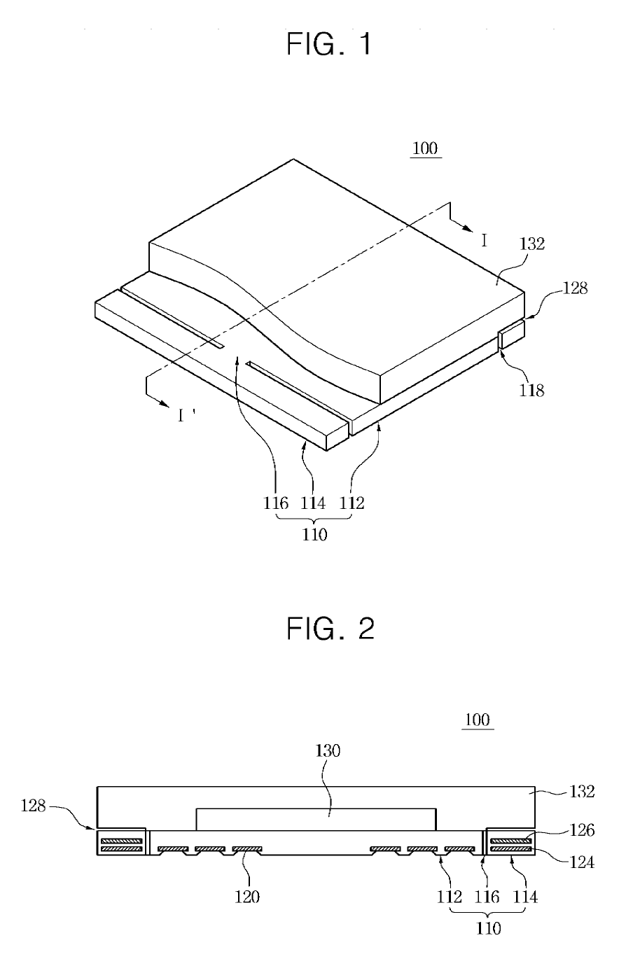

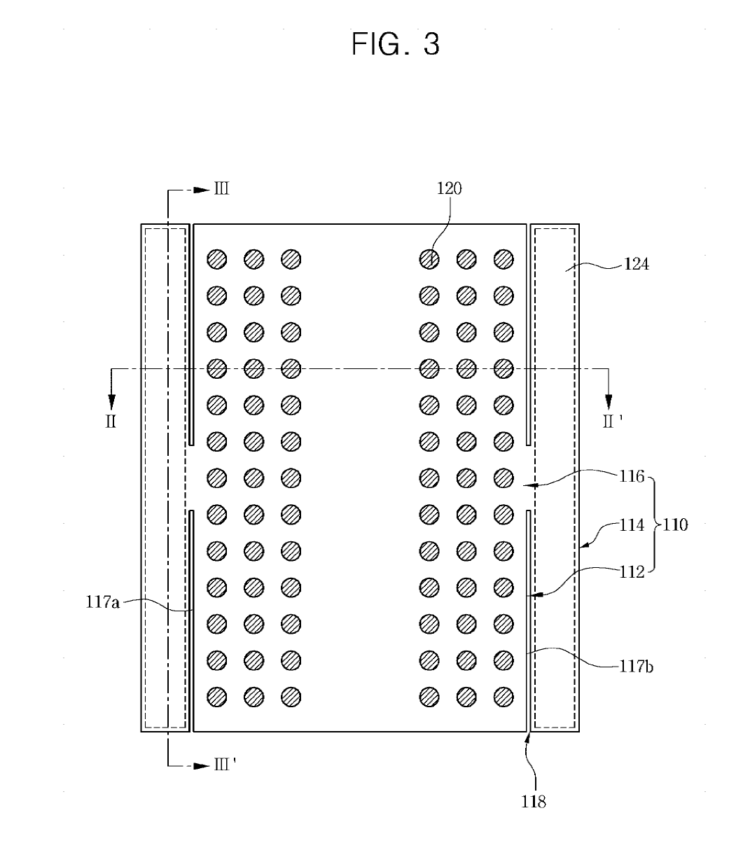

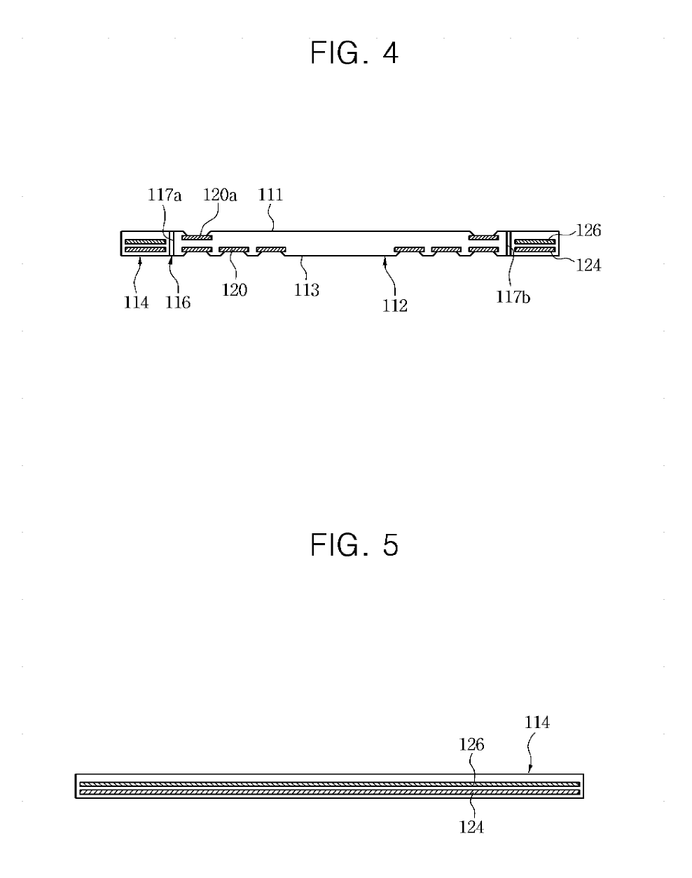

FIG. 1 is a schematic perspective view of a semiconductor package according to a first exemplary embodiment. FIG. 2 is a cross-sectional view taken along line I-I′ of FIG. 1. FIG. 3 is a plan view showing a lower surface of the semiconductor package of FIG. 1. FIG. 4 is a cross-sectional view taken along line II-IF of FIG. 3. FIG. 5 is a cross-sectional view taken along line III-III′ of FIG. 3.

Referring to FIGS. 1 and 2, a semiconductor package 100 according to this exemplary embodiment may include a semiconductor-package substrate 110, a semiconductor chip 130, and a mold unit 132 formed on the substrate 110.

The substrate 110 may include a body 112, first plate units 114, and fixing parts 116 connecting the body 112 to the first plate units 114.

The semiconductor chip 130 disposed on the substrate 110 may be electrically connected to the substrate 110 through connection members (not shown) such as metal wires or bumps.

The mold unit 132 may be formed on the substrate 110 to protect the semiconductor chip 130 and the connection members. The mold unit 132 may be formed of epoxy molding compound (EMC), for example. The mold unit 132 may be formed on the body 112, the first plate unit 114, and the fixing part 116 of the substrate 110. Further, although not shown, the mold unit 132 may be formed only on the body 112 or on the body 112 and the fixing parts 116 because of space limitations.

Referring to FIGS. 3 to 5, the substrate 110 may be a printed circuit board (PCB) having the body 112, the first plate units 114, and the fixing parts 116 integrated therein. The substrate 110 may include a plurality of insulating layers (not shown), first and second interconnection layers 120 and 120a for electrical connection, and a solder mask (not shown) partially exposing the interconnection layers 120 and 120a.

The body 112 and the first plate units 114 may have a rectangular shape when seen from the plan view. The body 112 may have an upper surface 111 and a lower surface 113 facing the upper surface 111. In the first and second interconnection layers 120 and 120a, first interconnection layer 120 disposed on the lower surface 113 may be a ball land pattern. The second interconnection layer 120a disposed on the upper surface 111 may be a connection pattern which is electrically connected to the semiconductor chip 130.

A pair of first plate units 114 may be disposed outside a first edge 117a of the body 112 and a second edge 117b facing the first edge 117a. The fixing parts 116 may physically connect the body 112 to the first plate units 114.

The first and second edges 117a and 117b of the body 112, disposed in opposite sides, may have the same length as the first plate units 114. The first and second edges 117a and 117b of the body 112 may have a larger length than the first plate units 114 disposed on opposite sides.

The pair of first plate units 114 may have the same length. The fixing parts 116 may be formed between central portions of the first plates 114 facing the fixing parts 116 and the first and second edges 117a and 117b of the body 112. Accordingly, distances from the fixing part 116 to both ends of the first plate unit 114 may be equal to each other. Between the first and second edges 117a and 117b of the body 112 and the first plate units 114, first spaces 118 may be formed by the fixing parts 116. The first spaces 118 may be formed by a punching or cutting process.

The first plate units 114 may include at least two metal layers having different thermal expansion coefficients, for example, first and second metal layers 124 and 126. The first and second metal layers 124 and 126 may have a plate shape, for example. The first and second metal layers 124 and 126 may be arranged in parallel to each other along the first and second edges 117a and 117b of the body 112. According an exemplary embodiment, the first and second metal layers 124 and 126 may be stacked to be spaced from each other with an insulating layer (not shown) interposed therebetween. The first and second metal layers 124 and 126 may have the same length and thickness. According to an exemplary embodiment, although not shown, the first and second metal layers 124 and 126 may have different lengths and thicknesses, and may be disposed to be attached to each other and stacked.

According to an exemplary embodiment, the first metal layer 124 may have the same thermal expansion coefficient as the first interconnection layer 120 formed on the body 112. That is, the first metal layer 124 may be formed of the same material through the same process as the first interconnection layer 120 formed on the body 112.

According to an exemplary embodiment, the second metal layer 126 may have a larger thermal expansion coefficient than the first metal layer 124. When a plurality of plates are stacked in the first plate unit 114, the thermal expansion coefficients of the metal layers may gradually decrease toward the lower surface 113 from the upper surface 111 of the substrate 110. Accordingly, when heat is applied to the substrate 110, the first plate unit 114 may be bent toward the first metal layer 124 having a relatively small thermal expansion coefficient. That is, both end portions of the first plate unit 114 may be bent toward the lower surface 113 of the substrate 110, with respect to the central portion fixed by the fixing part 116. The first and second metal layers 124 and 126 may be formed of a shape memory alloy.

Referring to FIGS. 1 and 2, second spaces 128 may be formed between the first plate units 114 and the mold unit 132. Accordingly, the first plate units 114 are separated from the mold unit 132, and the body 112 and the mold unit 132 may not be bent by the first plate units 114. Both end portions of the first and second metal layers 124 and 126 may be exposed to the outside such that the first plate units 114 can be easily bent in one direction.

Hereinafter, a method of manufacturing a semiconductor module using the semiconductor package according to the first exemplary embodiment will be described in detail.

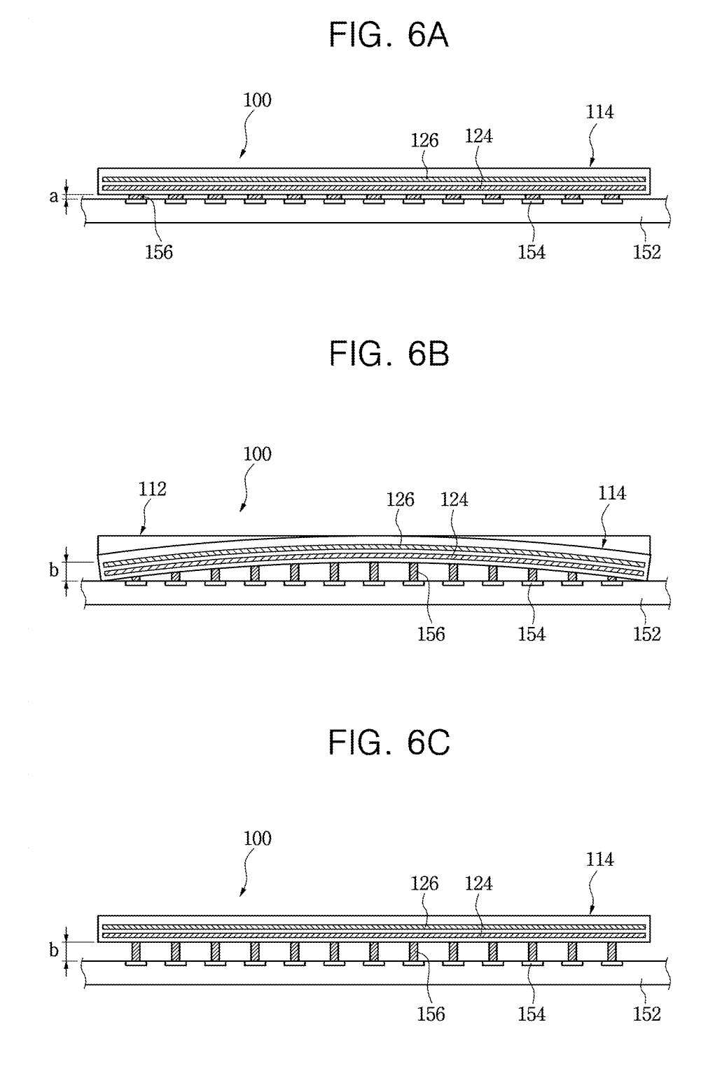

FIGS. 6A to 6C are cross-sectional views illustrating a method of manufacturing a semiconductor module using the semiconductor package according to the first exemplary embodiment.

FIGS. 6A to 6C include substantially the same components as the semiconductor package and the semiconductor-package substrate illustrated and described in FIGS. 1 to 5. Therefore, duplicate descriptions of the same components will be omitted, and like names and reference numerals will be used for the same components.

Referring to FIG. 6A, the semiconductor package 100 illustrated in FIGS. 1 and 2 may be disposed on a module substrate 152 having a plurality of connection terminals 154. The module substrate 152 may be a PCB, for example.

A plurality of ball land patterns formed on the lower surface of the semiconductor package 100 may be formed at positions corresponding to the connection terminals 154 of the module substrate 152.

Connection members 156 for electrical connection may be disposed between the ball land patterns and the connection terminals 154. The connection members 156 may be solder paste. The connection members 156 may be formed on the connection terminals 154 of the module substrate 152 before the semiconductor package 100 is disposed. For example, the connection members 156 may be solder balls formed on the ball land patterns of the semiconductor package 100. The semiconductor package 100 may be spaced a predetermined distance (first height a) from the module substrate 152 through the connection members 156.

A pair of first plate units 114 may be disposed outside the edges of the body 112 of the semiconductor package 100 and connected to the body 112 by fixing parts 116. The fixing parts 116 may be disposed between the central portions of the first plate units 114 and the body 112. The first metal layer 124 of the first plate unit 114 may have a smaller thermal expansion coefficient than the second metal layer 126.

Referring to FIG. 6B, a thermal process such as a soldering process may be performed on the semiconductor package 100 and the connection members 156. At this time, the connection members 156 may be molten by heat and attached to the ball land patterns and the connection terminals 154 corresponding to the respective connection members 156. Further, the first and second metal layers 124 and 126 may be expanded by the heat at a similar temperature to the temperature at which the connection members 156 are molten. In this case, the first plate units 114 may be bent. As the second metal layer 126 has a larger thermal expansion coefficient than the first metal layer 124, both end portions of the first plate units 114 may be bent toward the module substrate 152. The bent end portions of the first plate units 114 may be closely attached onto the module substrate 152.

As the first plate unit 114 is bent, the first plate unit 114 can raise the semiconductor package 100 from the module substrate 152. That is, a distance between the semiconductor package 100 and the module substrate 152 may increase to a second height b which is larger than the first height a. At this time, as the semiconductor package 100 is raised, the height of the molten connection members 156 increases to the second height b. That is, an aspect ratio of the connection members 156 may increase.

The height increase of the connection members 156 can be adjusted depending on the bending degree of the first plate units 114.

Referring to FIG. 6C, as the thermal process is completed, connection members 156 may be formed. As the distance between the semiconductor package 100 and the module substrate 152 increases, an aspect ratio of the connection members 156 increases. The first plate unit 114 may be disposed parallel to the module substrate 152 as the first and second metal layers 124 and 126 contract.

As such, as the connection members 156 having a large aspect ratio are formed using the semiconductor package having the plate units bent by heat, it is possible to manufacture a semiconductor module having stable TC reliability.

### Second Exemplary Embodiment

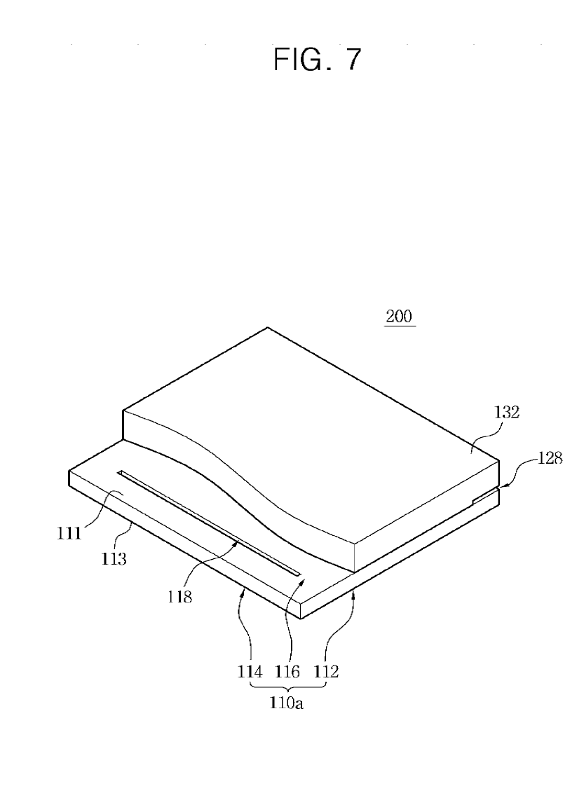

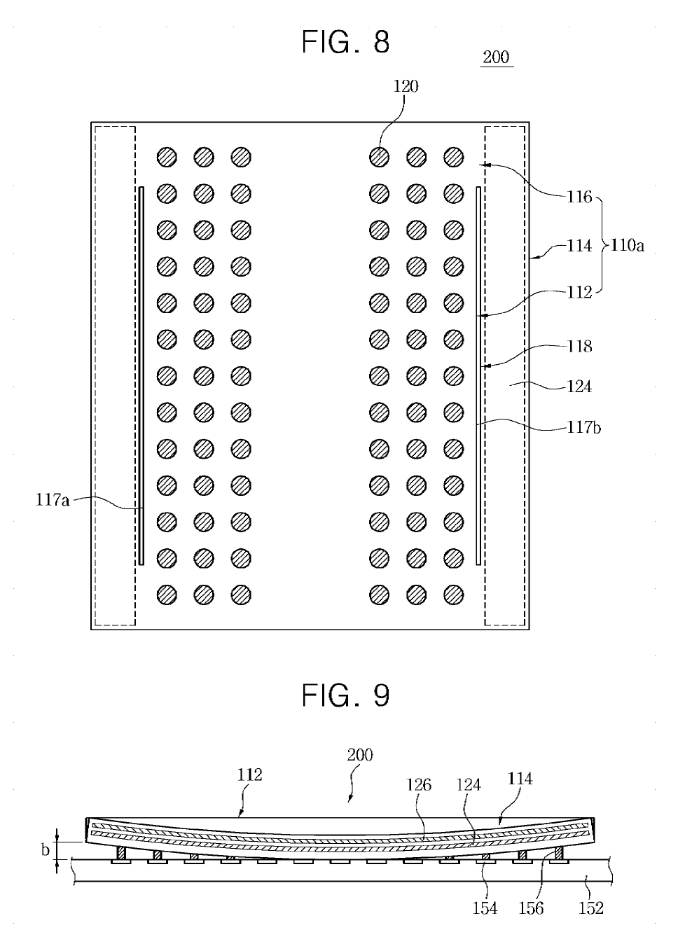

FIG. 7 is a schematic perspective view of a semiconductor package according to a second exemplary embodiment. FIG. 8 is a plan view showing a lower surface of the semiconductor package of FIG. 7.

FIGS. 7 and 8 include substantially the same components as the semiconductor package illustrated and described in FIGS. 1 to 2. Therefore, duplicate descriptions of the same components will be omitted, and like names and reference numerals will be used for the same components.

Referring to FIGS. 7 and 8, a semiconductor package 200 according to this exemplary embodiment may have a semiconductor-package substrate 110a including a body 112, a pair of first plate units 114, and fixing parts 116 connecting the body 112 to the first plates 114.

The fixing parts 116 may be formed between both end portions of the first plate units 114 and first and second edges 117a and 117b of the body 112. First spaces 118 may be formed between the first and second edges 117a and 117b of the body 112 and the first plate units 114 by the fixing parts 116. Second spaces 128 may be formed between the mold unit 132 and the first plate units 114.

The first plate units 114 may have first and second metal layers 124 and 126 (not shown) stacked therein. The second metal layer 126 disposed at the upper part may have a smaller thermal expansion coefficient than the first metal layer 124. That is, when a plurality of plates are stacked in the first plate unit 114, the thermal expansion coefficients of the metal layers may gradually increase toward the lower surface 113 from the upper surface 111 of the substrate 110a.

Accordingly, when heat is applied to the substrate 110a, both end portions of the first plate unit 114 may be bent so that they can be raised to a higher position than the central portion of the first plate unit 114 in a horizontal direction.

FIG. 9 is a cross-sectional view illustrating a method of manufacturing a semiconductor module using the semiconductor package according to the second exemplary embodiment.

FIG. 9 includes substantially the same components as in the method illustrated and described in FIGS. 6A to 6C. Therefore, duplicate descriptions of the same components and processes will be omitted, and like names and reference numerals will be used for the same components.

Referring to FIG. 9, the semiconductor package 200 illustrated in FIG. 8 may be disposed on a module substrate 152 having a plurality of connection terminals 154 through connection members 156. The fixing parts 116 may be disposed between both end portions of the first plate units 114 and the body 112. The first metal layer 124 of the first plate unit 114 may have a larger thermal expansion coefficient than the second metal layer 126 disposed on the first metal layer 124.

A soldering process may be performed on the semiconductor package 200 and the connection members. As the first metal layer 124 has a larger thermal expansion coefficient than the second metal layer 126, the central portion of the first plate unit 114 may be bent toward the module substrate 152. The bent central portion of the first plate unit 114 may be closely attached to the module substrate 152.

As the first plate units 114 are bent, the first plate units 114 can push up the semiconductor package 200 from the module substrate 152. Accordingly, the height of the molten connection members 156 increases. In this case, the connection members 156 may have a second height b larger than before the thermal process.

As the thermal process is completed, connection members 156, of which the height increases and the aspect ratio increases, may be formed between the semiconductor package 100 and the module substrate 152.

### Third Exemplary Embodiment

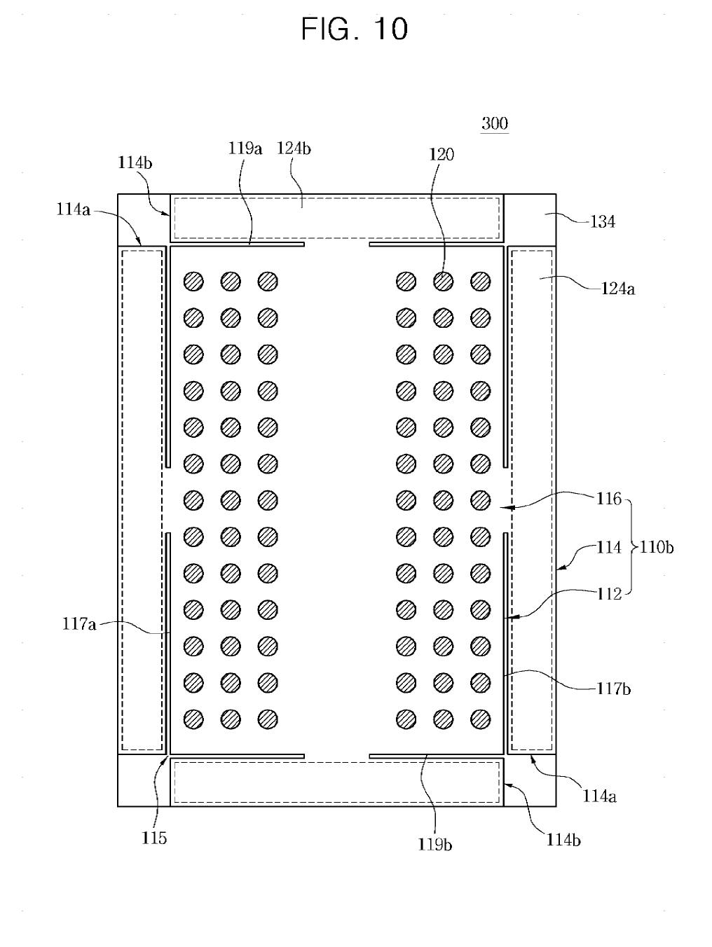

FIG. 10 is a plan view showing a lower surface of a semiconductor package according to a third exemplary embodiment.

FIG. 10 includes substantially the same components as the semiconductor package illustrated and described in FIGS. 1 and 2. Therefore, duplicate descriptions of the same components will be omitted, and like names and reference numerals will be used for the same components.

Referring to FIG. 10, a semiconductor package 300 according to this exemplary embodiment may have a semiconductor-package substrate 110b including a body 112, first plate units 114a and second plate units 114b, and fixing parts 116 connecting the body 112 to the first plate units and second plate units 114a and 114b.

The first plate units 114a and second plate units 114b may be disposed outside first through fourth edges 117a, 117b, 119a, and 119b of the body 112. The fixing parts 116 may be formed between central portions of the first plate units 114a and first and second edges 117a and 117b, and second plate units 114b and third and fourth edges 119a, and 119b of the body 112.

Each pair of plate units within the first and second plate units 114a and 114b may be disposed on opposite sides of body 112 and may have the same length. When seen from the plan view, the first and second plate units 114a and 114b may be disposed perpendicular to each other along the first through fourth edges 117a, 117b, 119a, and 119b of the body 112. The first plate units 114a may have a different length from the second plate units 114b. At this time, the first metal layers 124a and 124b may be formed inside the first and second plate units 114a and 114b disposed perpendicular to each other and a second metal layer (not shown) may be formed of materials having different thermal expansion coefficients. According to an exemplary embodiment, the number of plates disposed on the first plate units 114a may be different from the number of plates disposed on the second plate units 114b. In this case, both end portions of the first and second plate units 114a and 114b having different lengths and disposed perpendicular to each other may be bent to the same height by heat.

Further, although not shown, the fixing parts 116 may be formed between both end portions of the first and second plate units 114a and 114b and the edges of the body.

A method of manufacturing a semiconductor module using the semiconductor package 300 according to this exemplary embodiment is the same as that of FIGS. 6A to 6C. Accordingly, the detailed descriptions thereof will be omitted.

### Fourth Exemplary Embodiments

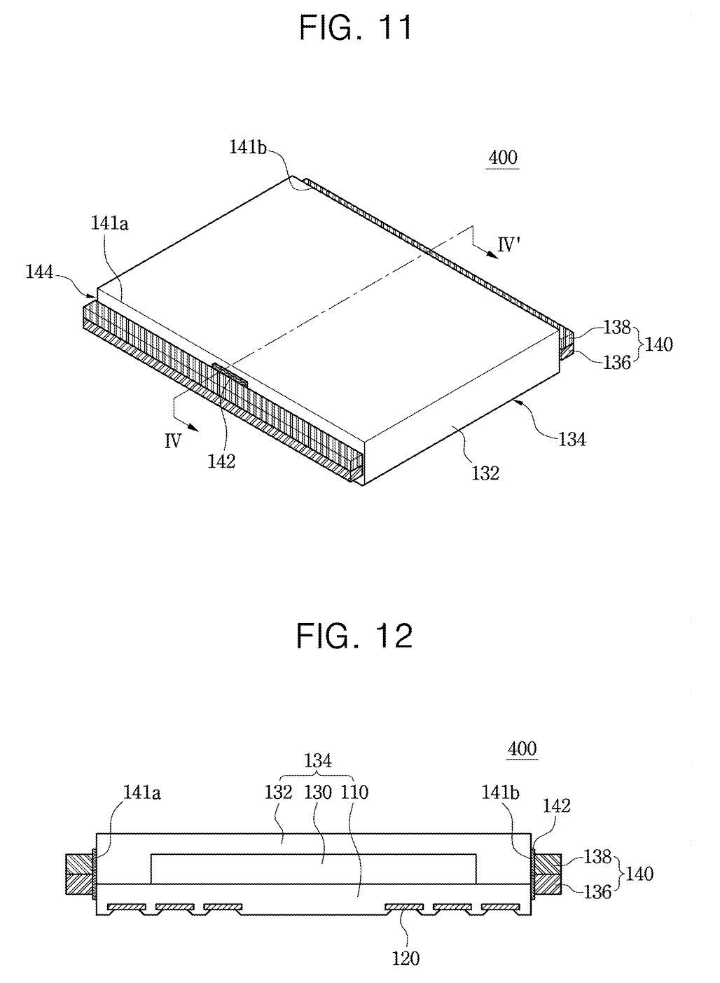

FIG. 11 is a perspective view of a semiconductor package according to a fourth exemplary embodiment. FIG. 12 is a cross-sectional view taken along line IV-IV′ of FIG. 11.

Referring to FIGS. 11 and 12, a semiconductor package 400 according to this exemplary embodiment may include a package body 134, a pair of third plate units 140, and fixing members 142 physically connecting the package body 134 to the third plate units 140.

Referring to FIGS. 11 and 12, the package body 134 may have a package shape including a substrate 110, a semiconductor chip 130, and a mold unit 132. The semiconductor chip 130 may be disposed on the substrate 110 and electrically connected to the substrate 110. The mold unit 132 may be formed on the substrate 130 to cover the semiconductor chip 130. When seen from the plan view, the package body 134 and the third plate units 140 may be formed in a rectangular shape.

The substrate 110 may be a PCB having a first interconnection layer 120 in the form of ball land patterns. The semiconductor chip 130 may be electrically connected to the substrate 110 through connection members (not shown) such as metal wires or bumps.

Each of the third plate units 140 may have a bar-shaped bi-metal structure in which third and fourth metal layers 136 and 138 having different thermal expansion coefficients are stacked. The third and fourth metal layers 136 and 138 may be formed of various metals and alloys including a copper-zinc alloy and nickel-iron alloy. The third plate units 140 may be disposed at one edge 141a of the package body 134 and the other edge 141b of the package body 134 facing the one edge 141a to be spaced from the package body 134.

The third plate units 140 may be physically attached to the package body 134 through the fixing members 142. The fixing members 142 may be an adhesive member such as an adhesive agent or tape. The fixing members 142 may have a property such that they are molten or their adhesive strength does not change in a thermal process such as a soldering process.

According to an exemplary embodiment, the lengths of the edges 141a and 141b of the package body 134 facing each other may be different from those of the third plate units 140. According to an exemplary embodiment, the lengths of the third plate units 140 may be equal to each other. The heights of the third plate units 140 may be smaller than that of the package unit 134. Although not shown, the heights of the third plate units 140 may be equal to that of the package body 134.

The fixing members 142 may be formed between central portions of the third plate units 140 and the edges 141a and 141b of the package body 134. Therefore, lengths from the fixing member 142 to both end portions of the third plate unit 140 may be equal to each other. Between the edges 141a and 141b of the package body 134 and the third plate units 140, third spaces 144 may be formed such that their ends are opened by the fixing members 142.

The third and fourth metal layers 136 and 138 may have the same length and thickness. However, depending on process conditions, the third and fourth metal layers 136 and 138 may have different lengths and thicknesses.

A third metal layer 136 may have a smaller thermal expansion coefficient than a fourth metal layer 138. Accordingly, when heat is applied to the third plate units 140, the fourth metal layer 138 may be bent toward the third metal layer 136 having a relatively small thermal expansion coefficient. That is, the third plate units 140 may be bent toward the lower surface 113 of the package body 134. Therefore, when heat is applied to the semiconductor package 400, the third plate units 140 may be bent so that both end portions thereof have a position lower than the fixed central portion thereof in a horizontal direction. At this time, the package body 134 is not bent by the bending of the third plate units 140, because of the third spaces 144. Although not shown, the third and fourth metal layers 136 and 138 may have insulating layers formed on the outer surfaces thereof.

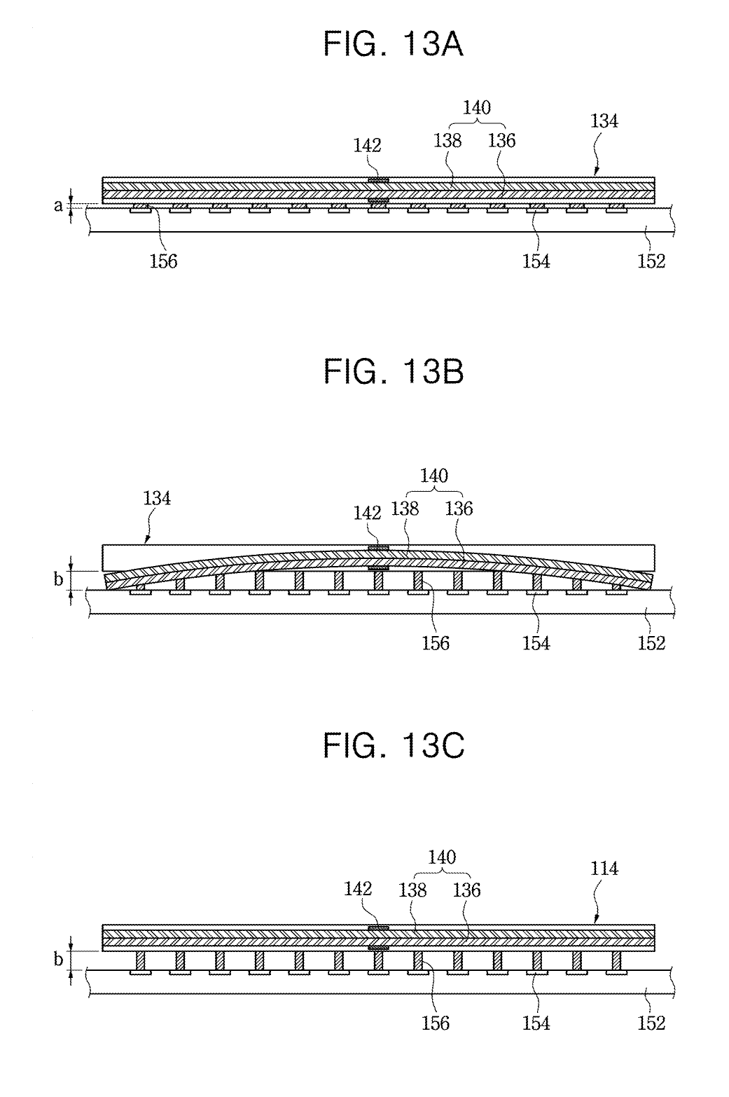

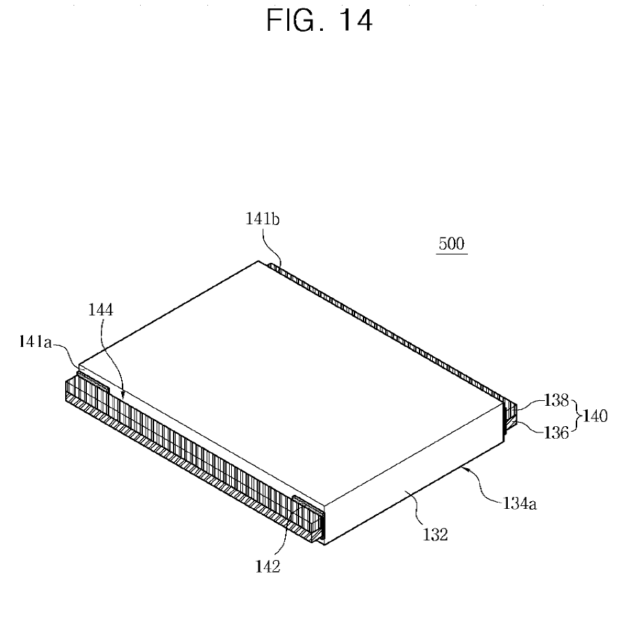

FIGS. 13A to 13C are cross-sectional views illustrating a method of manufacturing a semiconductor module using the semiconductor package according to the fourth exemplary embodiment.

FIGS. 13A to 13C include substantially the same components as the semiconductor package illustrated and described in FIGS. 11 and 12. Therefore, duplicate descriptions of the same components will be omitted, and like names and reference numerals will be used for the same components.

Referring to FIG. 13A, the semiconductor package 400 illustrated in FIGS. 11 and 12 may be disposed on the module substrate 152 having a plurality of connection terminals 154. Connection members 156 for electrical connection may be disposed between the package body 134 of the semiconductor package 400 and the connection terminals 154 of the module substrate 152. The semiconductor package 400 may be disposed to be spaced a predetermined distance (first height a) from the module substrate 152 through the connection members 156.

The fixing members 142 may be disposed between the central portions of the third plate units 140 and the package body 134. The third metal layer 136 of the third plate unit 140 may have a smaller thermal expansion coefficient than the fourth metal layer 138 disposed on the third layer 136.

Referring to FIG. 13B, a soldering process may be performed on the semiconductor package 400 and the connection members 156. At this time, both end portions of the third plate units 140 may be bent toward the module substrate 152 at a similar temperature to a reflow temperature.

As the third plate units 140 are bent, the third plate units 140 may push the semiconductor package 400 up from the module substrate 152. That is, the semiconductor package 400 and the module substrate 152 may extend as much as a second height b which is larger than the first height a. At this time, as the semiconductor package 100 is pushed up, the height of the molten connection members 156 may increase to the second height b. That is, an aspect ratio of the connection members 156 may increase.

Referring to FIG. 13C, as the thermal process is completed, connection members 156, of which the height increases and thus the aspect ratio increases, may be formed between the semiconductor package 100 and the module substrate 152. The third plate units 140 may be arranged parallel to the module substrate 152 as the third and fourth metal layers 136 and 138 contract.

### Fifth Exemplary Embodiment

FIG. 14 is a perspective view of a semiconductor package according to a fifth exemplary embodiment.

FIG. 14 includes substantially the same components as the semiconductor package illustrated and described in FIGS. 11 and 12. Therefore, duplicate descriptions of the same components will be omitted, and like names and reference numerals will be used for the same components.

Referring to FIG. 14, a semiconductor package 500 according to this exemplary embodiment may include a package body 134a, a pair of third plate units 140, and fixing members 142 connecting the package body 134a to the third plate units 140.

The fixing parts 142 may be disposed between both end portions of the third plate units 140 and one edge 141a and the other edge 141b of the package body 134a.

The third plate units 140 may have a third metal layer 136 having a relatively large thermal expansion coefficient and a fourth metal layer 138 disposed on the third metal layer 136 and having a relatively small thermal expansion coefficient.

Accordingly, when heat is applied to the third plate units 140, the third plate units 140 may be bent so that the central portions thereof have a higher position than the fixed end portions thereof in a horizontal direction.

A method of manufacturing a semiconductor module using the semiconductor package 500 according to this exemplary embodiment is the same as that of FIG. 9. Therefore, the detailed descriptions thereof will be omitted.

In addition, however, in the method of manufacturing a semiconductor module using the semiconductor package 500 according to this exemplary embodiment, a clip part fixing the plate units may be used.

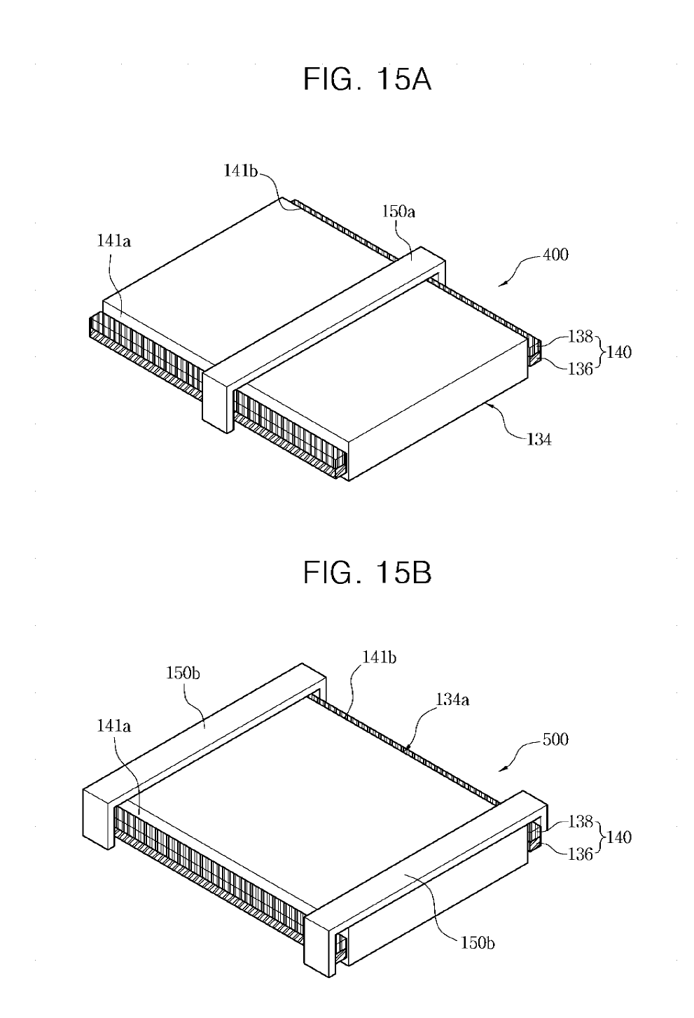

FIGS. 15A and 15B are perspective views of the semiconductor package having a clip part mounted thereon according to this exemplary embodiment.

FIGS. 15A and 15B include substantially the same components as the semiconductor package illustrated and described in FIGS. 11 and 14. Therefore, duplicate descriptions of the same components will be omitted, and like names and reference numerals will be used for the same components.

Referring to FIGS. 15A and 15B, a method of manufacturing a semiconductor module according to this exemplary embodiment may include first and second clip parts 150a and 150b disposed on the semiconductor packages 400 and 500 illustrated in FIGS. 11 and 14, respectively. The first and second clip parts 150a and 150b may be disposed to fix the third plate units 140 disposed on the semiconductor packages 400 and 500.

Referring to FIG. 15A, the fixing members 142 of the semiconductor package 400 may be formed at the central portions of the second plate units 140 disposed on opposite sides and one and the other edges 141 and 141b of the package body 134. The first clip part 150a may be disposed in a clip shape at the third plate units 140 having the fixing members 142 and the central portion of the package body 134.

Referring to FIG. 15B, the fixing members 142 of the semiconductor package 500 may be formed at both end portions of the third plate units 140 and one and the other edges 141a and 141b of the package body 134a. The second clip parts 150b may be disposed in such a clip shape as to cross both end portions of the package body 134a and the third plate units 140 having the fixing members 142.

Accordingly, the third plate units 140 can be more strongly fixed to the package body 134 by the first and second clip parts 150a and 150b. Therefore, it is possible to prevent the third plate units 140 from being detached from the package body 134 in the process of forming the semiconductor module. Further, as the first and second clip parts 150a and 150b accurately support the connection portions between the third plate units 140 and the package body 134, it is possible to constantly maintain the height of the third plate units 140 which are to be bent.

The first and second clip parts 150a and 150b may be removed after the process of manufacturing the semiconductor module.

### Sixth Exemplary Embodiment

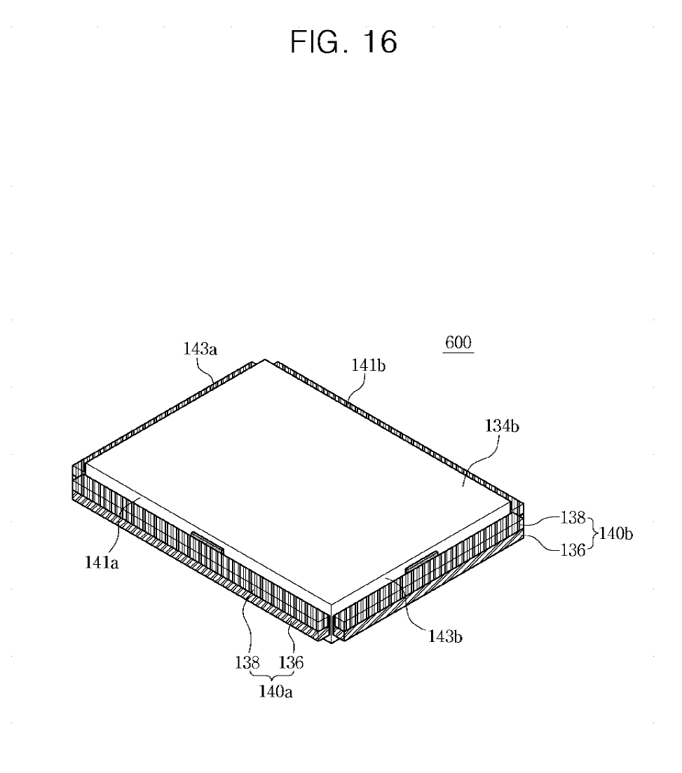

FIG. 16 is a perspective view of a semiconductor package according to a sixth exemplary embodiment.

FIG. 16 includes substantially the same components as the semiconductor package illustrated and described in FIGS. 11 and 12. Therefore, duplicate descriptions of the same components will be omitted, and like names and reference numerals will be used for the same components.

Referring to FIG. 16, a semiconductor package 600 according to this exemplary embodiment may include a package body 134b, fourth and fifth plate units 140a and 140b, and fixing members 142 connecting the package body 134b to the fourth and fifth plate units 140a and 140b.

The fourth and fifth plate units 140a and 140b may be disposed outside all the edges 141a, 141b, 143a, and 143b of the package body 134b. The fourth and fifth plate units 140a and 140b may be physically attached to the package body 134b through the fixing member 142.

Each pair of plate units with in the fourth and fifth plate units 140a and 140b may be disposed on opposite sides of package body 134b and may have the same length. When seen from the plan view, the fourth and fifth plate units 140a and 140b disposed perpendicular to each other and may have different lengths. At this time, the third metal layers 136 and the fourth metal layers 138 composing the fourth and fifth plate units 140a and 140b may be formed of materials having different thermal expansion coefficients. Further, the number of plates disposed on the fourth plate units 140a may be different from the number of plates disposed on the fifth plate units 140b. In this case, both end portions of the fourth and fifth plate units 140a and 140b having different lengths and disposed perpendicular to each other may be bent to the same height by heat.

### Seventh Exemplary Embodiment

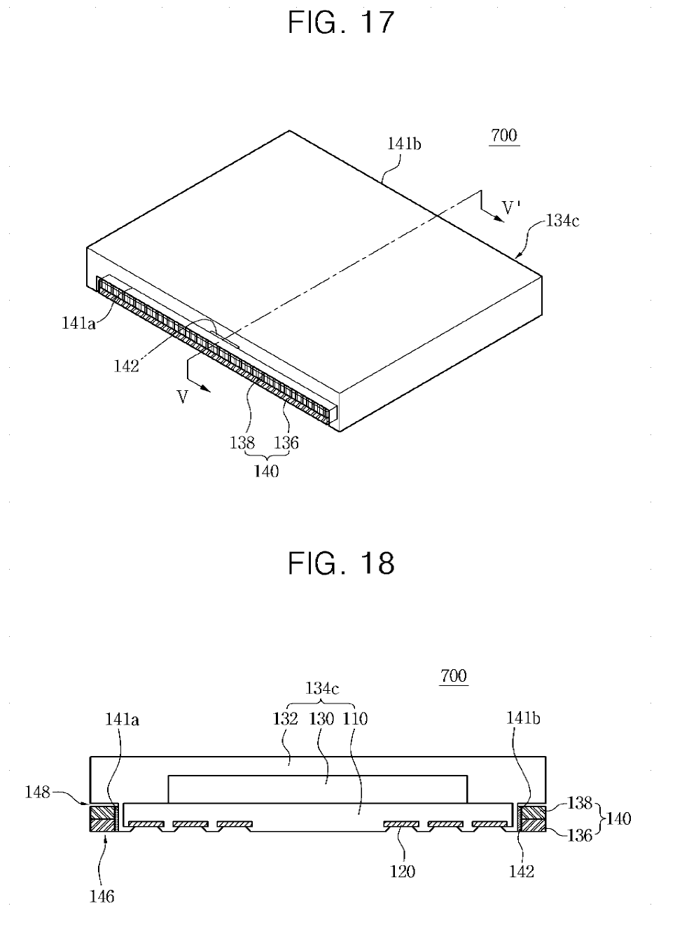

FIG. 17 is a perspective view of a semiconductor package according to a seventh exemplary embodiment. FIG. 18 is a cross-sectional view taken along line V-V′ of FIG. 17.

FIGS. 17 and 18 include substantially the same components as the semiconductor package illustrated and described in FIGS. 11 and 12. Therefore, duplicate descriptions of the same components will be omitted, and like names and reference numerals will be used for the same components.

Referring to FIGS. 17 and 18, a semiconductor package 700 according to this exemplary embodiment may include a package body 134c, third plate units 140, and fixing members 142 connecting the package body 134c to the third plate units 140.

The package body 134c may have a package shape including a substrate 110, a semiconductor chip 130 disposed on the substrate 110, and a mold unit 132 disposed on the substrate 110 and covering the semiconductor chip 130.

The mold unit 132 may be formed to extend outside the edges of the semiconductor chip 130 and the substrate 110. The package body 134c may have spaces 146 provided at one edge 141a and the other edge 141b by the extending mold unit 132. The third plate units 140 may be disposed under the extending mold unit 132, that is, in the spaces 146. The third plate units 140 may be physically attached to the package body 134c through the fixing members 142. Each of the third plate units 140 disposed in the spaces 146 may include a third metal layer 136 having a relatively small thermal expansion coefficient and a fourth metal layer 138 having a relatively large thermal expansion coefficient. The third plate units 140 disposed in the spaces 146 may have the same length. Fourth spaces 148 may be formed between the third plate units 140 and the mold unit 132. Accordingly, the third plate units 140 can have independent movement from the mold unit 132. The fixing members 142 may be formed between central portions of the third plate units 140 and the edges 141a and 141b of the package body 134c. Accordingly, distances from the fixing member 142 to both end portions of the third plate units 140 may be equal to each other. Therefore, when heat is applied to the third plate units 140, both end portions of the third plate units 140 may be bent toward a lower surface of the package body 134c.

Although not shown, the fixing members 142 may be formed between both end portions of the third plate units 140 and the edges 141a and 141b of the package body 134c. At this time, the third metal layer 136 of the third plate unit 140 may have a larger thermal expansion coefficient than the fourth metal layer 138 disposed on the third metal layer 136.

The third plate units 140 may be formed at all the edges of the package body 134c, that is, two pairs of third plate units 140 may be formed.

A method of manufacturing a semiconductor module using the semiconductor package 700 according to this exemplary embodiment is the same as that of FIGS. 13A to 13C. Accordingly, the detailed descriptions thereof will be omitted.

In the exemplary embodiments, the height of the connection patterns formed between the semiconductor package and the module substrate can be adjusted using the plate units formed at the edges of the semiconductor package and having stacked metal layers having different thermal expansion coefficients.

Therefore, the connection patterns having a large aspect ratio can be formed between the semiconductor package and the module substrate, which makes it possible to form a semiconductor module having improved TC reliability of the electrical connection portions.

According to the exemplary embodiments, an aspect ratio of a connection pattern formed between a semiconductor package and a module substrate can be adjusted using a plate bent by applying heat to the plate having different metal layers of different thermal expansion coefficients.

Accordingly, it is possible to manufacture a semiconductor module in which TC reliability of the connection pattern connecting the semiconductor package to the module substrate is improved.

The foregoing is illustrative of exemplary embodiments and is not to be construed as limiting thereof. Although a few exemplary embodiments have been described, those skilled in the art will readily appreciate that many modifications are possible in the exemplary embodiments without materially departing therefrom. Accordingly, all such modifications are intended to be included within the scope of the claims. In the claims, means-plus-function clauses are intended to cover the structures described herein as performing the recited function, and not only structural equivalents but also equivalent structures. Therefore, it is to be understood that the foregoing is illustrative of various exemplary embodiments and is not to be construed as limited to the specific embodiments disclosed, and that modifications to the disclosed embodiments, as well as other embodiments, are intended to be included within the scope of the appended claims.

What is claimed is:

1. A method of manufacturing a semiconductor module, comprising:
forming a semiconductor package including one or more plate units;
aligning the semiconductor package on a module substrate to dispose at least one connection member between the semiconductor package and the module substrate; and
applying heat to the one or more plate units and the at least one connection member to increase a distance between the module substrate and the semiconductor package.

2. The method according to claim 1, wherein forming the semiconductor package comprises:
forming a substrate having a body, the one or more plate units, and one or more fixing parts connecting the body to the one or more plate units, wherein the one or more plate units include at least two metal layers having different thermal expansion coefficients;
forming a semiconductor chip on the substrate to be electrically connected to the substrate; and
forming a mold unit covering the semiconductor chip on the substrate.

3. The method according to claim 2, wherein at least one of the one or more plate units is formed outside an edge of the body.

4. The method according to claim 2, wherein the one or more plate units include a first plate unit and a second plate unit disposed outside opposite edges of the body.

5. The method according to claim 2, wherein at least one plate unit of the one or more plate units is formed outside each edge of the body.

6. The method according to claim 5, wherein one of the one or more plate units is spaced apart from another of the one or more plate units.

7. The method according to claim 2, wherein the one or more fixing parts are formed between central portions of the one or more plate units and the body.

8. The method according to claim 7, wherein the thermal expansion coefficients of the at least two metal layers decrease as a distance between a metal layer of the at least two metal layers and the connection members decreases.

9. The method according to claim 2, wherein at least one fixing part of the one or more fixing parts is formed between an end portion of the one or more plate units and the body.

10. The method according to claim 9, wherein the thermal expansion coefficients of the at least two metal layers increase as a distance between a metal layer of the at least two metal layers and the connection members decreases.

11. The method according to claim 1, wherein forming the semiconductor package comprises:
forming a package body having a substrate, a semiconductor chip, and a mold unit, wherein the semiconductor chip is attached to the substrate, and the mold unit is formed on the substrate to cover the semiconductor chip; and
attaching the one or more plate units to one or more edges of the package body using one or more fixing parts, wherein the one or more plate units include at least two metal layers having different thermal expansion coefficients.

12. The method according to claim 11, wherein the at least two metal layers are formed of a bi-metal or shape memory alloy.

13. The method according to claim 1, wherein forming the semiconductor package comprises:
forming a substrate having a body, the one or more plate units, and one or more fixing parts connecting the body to the one or more plate units, wherein the one or more plate units include a first metal layer and a second metal layer;
forming a semiconductor chip on the substrate to be electrically connected to the substrate; and
forming a mold unit covering the semiconductor chip on the substrate;
wherein the first metal layer is closer to the at least one connection member than the second metal layer.

14. The method according to claim 13, wherein the second metal layer has a smaller thermal expansion coefficient than the first metal layer.

15. The method according to claim 13, wherein the second metal layer has a larger thermal expansion coefficient than the first metal layer.

16. The method according to claim 1, wherein the applying heat bends the one or more plate units such that a center portion of the one or more plate units moves away from the module substrate and an end portion of the one or more plate units moves toward the module substrate.

17. The method according to claim 1, wherein the applying heat bends the one or more plate units such that an end portion of the one or more plate units moves away from the module substrate and a center portion of the one or more plate units moves toward the module substrate.

18. The method according to claim 1, further comprising:
disposing a clip part on a central portion of the semiconductor package to fix the one or more plate units.

19. The method according to claim 2, further comprising:
disposing a first clip part on a first end portion of the semiconductor package, and a second clip part on a second end portion of the semiconductor package to fix the one or more plate units.

20. The method according to claim 2, wherein the one or more fixing parts include one or more spaces between the body and the one or more plate units.
